(19) United States
(12) Patent Application Publication
(10) Pub. No.: US 2007/0145495 A1
(43) Pub. Date: Jun. 28, 2007

(54) Method of fabricating a MOSFET transistor having an anti-halo for modifying narrow width device performance

(75) Inventors: Giuseppe Curello, Portland, OR (US); Sivakumar P. Mudanai, Hillsboro, OR (US); Nick Lindert, Beaverton, OR (US); Leonard C. Pipes, Beaverton, OR (US); M. Reaz Shaheed, Beaverton, OR (US); Sunit Tyagi, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/319,815

(22) Filed: Dec. 27, 2005

(51) Int. Cl. H01L 29/78; H01L 21/336

(52) U.S. Cl. 257/402; 438/289; 438/296

(57) ABSTRACT

A method including forming a transistor structure structure comprising a gate electrode over an active region of a substrate, the active region defined by a trench isolation structure and changing a performance of a narrow width transistor with respect to a wide width transistor by introducing a dopant into the active region adjacent an interface defined by the trench isolation structure and the gate electrode. A structure including a gate electrode formed on a substrate, an active region adjacent an interface defined by a trench isolation structure and a gate electrode and an implant within the active region to change a performance of a transistor.

### BACKGROUND

1. Field

Circuit devices and methods for forming circuit devices.

2. Background

A metal oxide semiconductor field effect transistor (MOSFET) of an integrated circuit such as a multiprocessor or other circuit. The transistor includes a source and drain junction region formed in a semiconductor substrate and a gate electrode formed on a surface of the substrate. A gate length is the distance between the source and drain junction region. Within the substrate, the region of the substrate beneath the gate electrode and between the source and drain junction regions is generally referred to as a channel with a channel length being the distance between the source and drain junctions. An active area including the gate electrode and the junction regions is typically defined by shallow trench isolation (STI) structures formed in the substrate defining a perimeter. The distance between two STI in a direction perpendicular to the channel (on the same substrate plane) is generally referred to as a channel width. In this aspect, trenches are etched vertically into the silicon substrate and a dielectric material (e.g., an oxide) is deposited within the trench. The term “vertical” as used herein is understood to mean substantially perpendicular to a surface of the substrate.

As noted above, many transistor devices are formed in a semiconductor substrate. To improve the conductivity of the semiconductor material of the substrate, dopants are introduced (e.g., implanted) into the substrate. An N-type transistor device may have source and drain regions (and gate electrode) doped with an N-type dopant such as arsenic. The N-type junction regions are formed in a well that has previously been formed in the semiconductor substrate as a P-type conductivity. A P-type dopant is boron.

A transistor device works generally in the following way. Carriers (e.g., electrons, holes) flow between source junction and drain junction by the establishment of contacts on the substrate to the source and drain junction between which a potential voltage difference has been applied. To establish carrier flow, a sufficient voltage must be applied also to the gate electrode to form an inversion layer of carriers in the channel. This minimum amount of voltage is generally referred to as a threshold voltage (V_{T}).

In general, in Very Large Scale Integrated (VLSI) circuits a variety of device lengths and widths are used (where “width” is the device dimension measured in the direction perpendicular to current flow and “length” is the device dimension measured in the direction of current flow). For an effective VLSI circuit design, it is desired that performance characteristics like threshold voltage V_{T}, leakage current I_{off} (i.e. current per micron of device width flowing between source and drain junctions in “off-state” when transistor is switched off) and drive current Iₒₙ (i.e. current per micron of device width flowing between source and drain junctions in “on-state” or when transistor is switched on) are well controlled and remain constant.

If drive current decreases on narrow width devices, designers typically will need to add additional device width to their layout to compensate for the drive current loss if high performance is required on the narrow width devices used. Once this is done on the millions of narrow devices present, it will result in undesirable increased microchip area. On the other hand if drive current Iₒₙ increases on narrow width devices due to a decrease in V_{T} and increase in leakage current I_{off}, designers will typically experience undesired high current leakage and high power consumption in circuit blocks which makes use of narrow width devices such as for example a SRAM (Static Random Access Memory) array.

Typically, for long devices (about 500-1000 nanometers channel length L), I_{off} increases while V_{T} decreases when going from wide to narrow width MOSFET. This effect is known as Inverse Narrow Width Effect (INWE) and is mainly due to the gate electrode wrapping around the isolation edges and high trench slopes that result in fringing (i.e., higher) electrical field at the STI edges. In contrast, in the case of short devices (about 30-70 nanometers channel length L), despite the type of isolation used, the opposite of INWE is observed and V_{T} increases while I_{off} decreases when going from wide to narrow width MOSFET. Ideally, the threshold voltage should be constant along the gate width especially for the short devices (about 30-70 nanometers channel length L) that are mostly used in state of the art VLSI.

To set the threshold voltage of the short devices (about 30-70 nanometers channel length L), locally implanted dopants may be introduced under the gate edges by tilted implants. Such implants are referred to as “halo” implants and are normally performed after gate patterning in a direction parallel to the channel length direction (perpendicular to the device width direction). The implanted dopant however tends to raise the doping concentration at both active region ends in the device width direction due to the implanted species segregation properties into the oxide material of which the STI trenches are formed. In this aspect, a piling up of the dopant at STI edge regions may be seen.

In the case where the dopant concentrations below the gate vary, so does a threshold voltage along the width of the gate. In particular in short channel length narrow width devices, as a result of diffusion and the piling up of the halo dopant toward the STI region, the threshold voltage at the edge regions of the gate electrode may be greater than at the center region. In wide devices this non uniform distribution does not significantly affect overall threshold voltage because the gate edges make up only a small fraction of the entire gate. In narrow devices, however, since the gate is much narrower, the contribution of the edges is much more significant. Thus, in narrow width devices (e.g., on the order of 500 nanometers width or less), the overall threshold voltage of the gate is increased to a greater degree due to the edges than in wide devices.

In addition, threshold voltage may be sensitive to STI step topography at STI edges that cause a poly gate to be thicker and a poly length to be patterned longer at device edges. Since threshold voltage varies with poly length, a local variation in poly length occurring at STI edge regions will change the average threshold voltage. This change in threshold voltage will be, larger on narrow width devices where the gate edges make up a large fraction of the entire gate.

### BRIEF DESCRIPTION OF THE DRAWINGS

The features, aspects, and advantages of the invention will become more thoroughly apparent from the following detailed description, appended claims, and accompanying drawings in which:

FIG. 1 is a schematic illustration of a side view of a portion of a semiconductor substrate having a photoresist layer and a mask layer overlying the substrate.

FIG. 2 is a schematic illustration of a side view of a semiconductor substrate having a photoresist layer and a mask layer overlying the substrate after etching a portion of the mask layer.

FIG. 3 is a schematic illustration of a side view of a semiconductor substrate having a photoresist layer and a mask layer overlying the substrate after etching a portion of the substrate layer.

FIG. 4 is a schematic illustration of a side view of a semiconductor substrate after removing a photoresist layer overlying a mask layer and substrate.

FIG. 5 is a schematic illustration of a side view of a semiconductor having an oxide layer deposited over a mask layer and substrate.

FIG. 6 is a schematic illustration of a side view of a semiconductor after polishing of the oxide layer deposited over a mask layer and substrate.

FIG. 7 is a schematic illustration of a side view of a semiconductor after etching of the oxide layer deposited over a mask layer and substrate.

FIG. 8 is a schematic illustration of a side view of a semiconductor after introducing an implant to an active region.

FIG. 9 is a schematic illustration of a side view of a semiconductor after etching of the mask layer deposited over the substrate

FIG. 10 is a schematic illustration of a side view of a semiconductor after applying a gate electrode to a mask layer deposited over the substrate.

FIG. 11 is a schematic illustration of a top view of a semiconductor after applying a gate electrode to a mask layer deposited over the substrate.

FIG. 12 is a cross section of a semiconductor after the processing operations of forming lightly doped junctions, sidewall spacers, source/drain junctions and halos.

FIG. 13 illustrates a flow chart of a method of fabricating a MOSFET transistor.

FIG. 14 shows a computer system including a microprocessor having transistors formed according to an embodiment shown in FIGS. 1-13.

### DETAILED DESCRIPTION

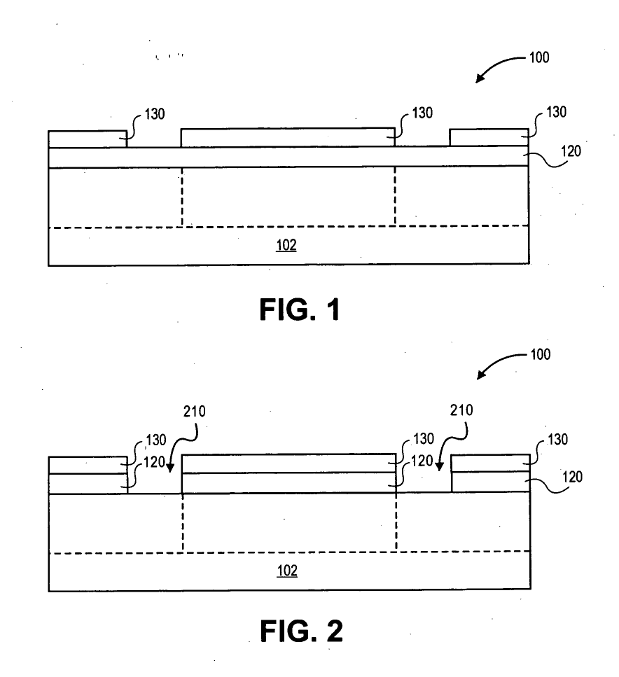

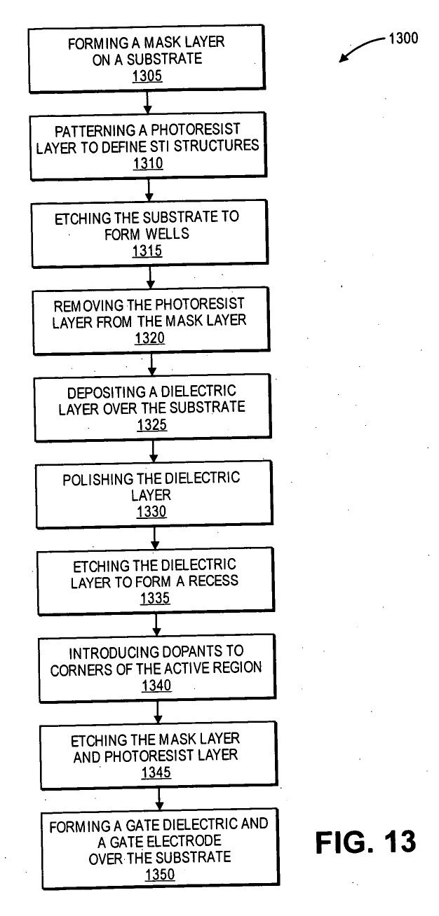

FIGS. 1-12 describe a method of fabricating a MOSFET transistor having an anti-halo for modifying narrow width device performance. FIG. 13 shows a flow chart 1300 of the method described in FIGS. 1-12.

Referring to the figures, FIG. 1 shows a structure 100 including substrate 102. Substrate 102 of structure 100 may be, for example, a single crystal semiconductor (e.g., silicon) material or a semiconductor-on-insulator (SOI) structure. Structure 100 may form part of a wafer in which multiple chips or die will be formed.

Overlying a surface of substrate 102 (a top surface as viewed) in FIG. 1 is mask layer 120. Mask layer 120 may be for example a silicon nitride (Si₃N₄) deposited to a representative thickness on the order of about 100 nanometers (nm) according to current technologies (block 1305, FIG. 13).

Overlying a surface of mask layer 120 in FIG. 1 (a top surface as viewed) is photoresist layer 130. Photoresist layer 130 is a positive photoresist material patterned to define areas (openings) for forming shallow trench isolation (STI) structures (block 1310, FIG. 13). Photoresist layer 130 may be patterned by techniques such as, but not limited to, applying a light-sensitive material over the desired area and removing the exposed material. It is to be appreciated that photoresist layer 130 serves as a further masking layer.

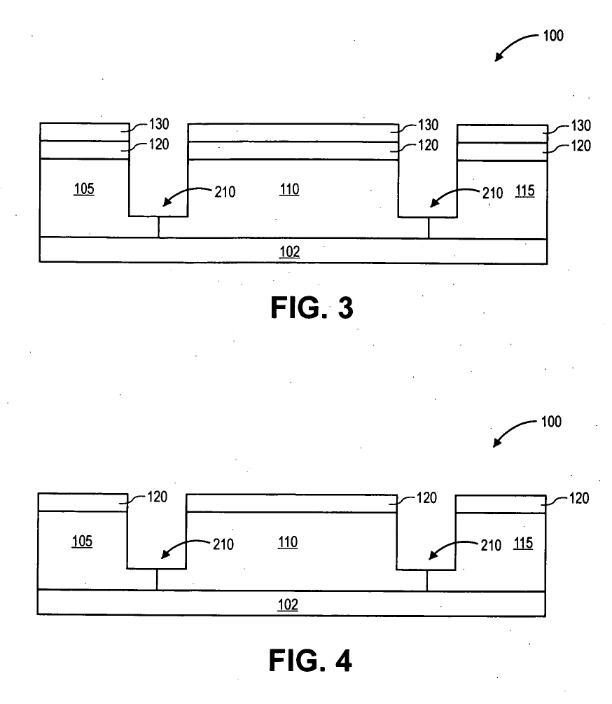

FIG. 2 shows the structure of FIG. 1 after the further processing operation of etching a portion of mask layer 120 with an etchant. Etchants may include, but are not limited to, liquid chemicals such as for example hot phosphoric acid for a mask layer material of Si₂N₄. Etching of mask layer 120 stops at substrate 102 leaving a portion of substrate 102 exposed. The exposed portion of substrate 102 is further etched as shown in FIG. 3 to form active areas or wells 105, 110 and 115 defined by trench 210 (block 1315, FIG. 13). In this embodiment, shallow trench 210 defines active areas or wells for individual transistor devices.

Wells 105, 110 and 115 may be P-type or N-type. For example, well 110 may be a P-type well formed in one region of substrate 102 while wells 105 and 115 may be N-type formed in a second and third region of substrate 102. P-type well 110 is formed by introducing a dopant such as boron, into substrate 102. N-type wells 105, 115 are formed by introducing a dopant such as arsenic, phosphorus, or antimony into substrate 102. Representatively, the transistor device formed by the foregoing description in well 110 is an NMOSFET, formed in a P-type well. In an alternative embodiment, the transistor device is a PMOSFET, formed in an N-type well.

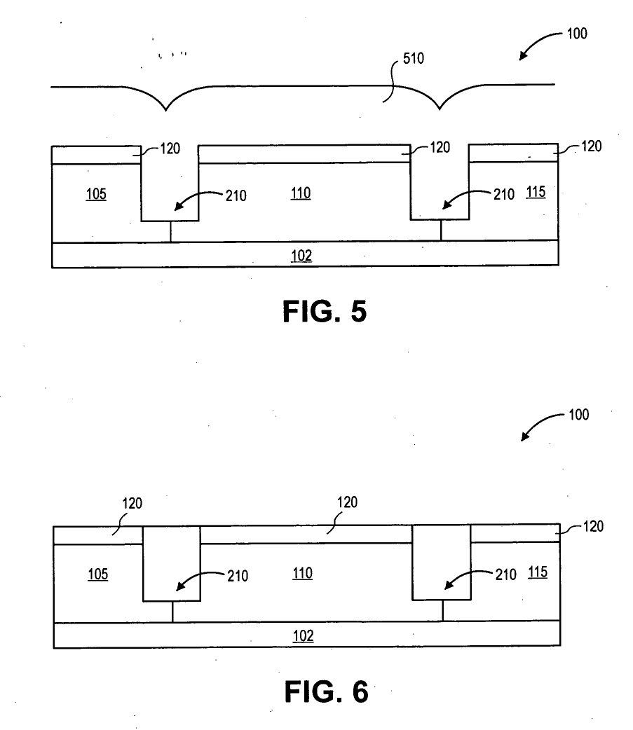

FIG. 4 shows semiconductor substrate 102 after the further processing operation of removing photoresist layer 130 from a surface of mask layer 120 (block 1320, FIG. 13). Photoresist layer 130 may be removed by, for example, a wet chemical processing or plasma stripping. FIG. 5 shows structure 100 of FIG. 4 after depositing a dielectric material 510 over substrate 102 (e.g., on a top surface as viewed) (block 1325, FIG. 13). Dielectric material 510 may be a silicon dioxide (SiO₂) material deposited (e.g., by chemical vapor deposition (CVD)) to a thickness to over fill trenches 210.

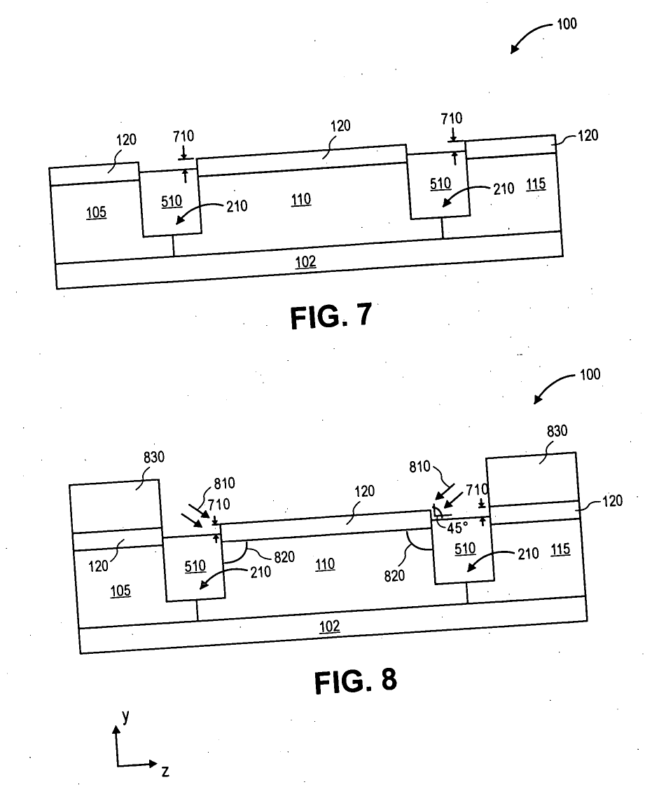

After dielectric layer 510 is formed, dielectric layer 510 is polished resulting in a planar surface of structure 100 as shown in FIG. 6 (a planar top surface as viewed) (block 1330, FIG. 13). Polishing may be achieved, for example by, a chemical mechanical polishing (CMP) technique or any similar technique providing a planarized substrate surface. Dielectric material 510 fills trench 210 but is otherwise removed from a surface of structure 100. Once planarized, dielectric layer 510 may be etched with an etchant to form a recess 710 as shown in FIG. 7 (block 1335, FIG. 13). Etchants may include, but are not limited to, hydrofluouric acid (HF) or any similar acid capable of etching dielectrics. In one embodiment, according to current technologies recess 710 is approximately 200-500 angstroms (Å) below an upper surface of mask layer 120.

FIG. 8 illustrates structure 100 of FIG. 7 after the further processing operation of introducing dopants 810 (e.g. anti-halo implants) to corners 820 of active region 110 (block 1340, FIG. 13). Dopants 810 are introduced in the device width direction (Z-axis) from laterally opposed sides of the gate.

In one embodiment, a narrow device width may be in the range of approximately 0.1-0.5 microns and a wide device width may be in the range of approximately 1-10 microns. Dopants 810 may be of a P-type or N-type species depending respectively on whether it is desired to increase or to decrease the V_{T} of the narrow width NMOS devices with respect to the V_{T} of the wide width NMOS devices.

In an ideal embodiment, device performance (I_{D}) remains constant regardless of the width (z) of the device. In reality, however, as the width (z) of the device decreases, the performance decreases dramatically. It is this performance decrease that, in one aspect, may be balanced and in another aspect overcompensated to achieve the target performance level. Thus, the energy and dose of the implant must be optimized to appropriately balance the ion distribution within the well and achieve target V_{T}.

In one embodiment, the species of the dopant is chosen in order to compensate or to boost a nonuniform distribution of dopant along the substrate surface after doping of the substrate well. In another embodiment, species of the dopant is chosen in order to compensate or to boost a nonuniform distribution of dopant along a substrate surface after a halo implant performed after poly gate formation. A nonuniform distribution refers to a distribution differing by 50 to 100 percent. Alternatively, the dopant is introduced to compensate for a performance decrease with respect to wide ones cause by a thicker poly gate at STI edges and a poly length patterned longer at device edges. In one embodiment an opposite species type to the halo may be selected if one wants to reduce the overall V_{T} of the narrow device with respect to the V_{T} of the wide width devices.

Nonuniform ion distribution occurs, in one aspect, during thermocycles of the fabrication process. In the case of a P-type well, boron dopants tend to diffuse toward dielectric material 510 (e.g., SiO₂) in trench 210. Thus, a larger concentration of boron tends to form along edges of well 110 than at the center. This increased boron concentration near edges of a width dimension of a gate electrode tends to increase the voltage that must be applied to the edges to turn the device on as compared to that required along the center portion of a width dimension of a gate electrode. In a narrow width device, where edge regions represent a large percentage (approximately 10-40 percent (%)) of the entire width amount, this results in overall higher device V_{T}. In the wide devices instead, where edge regions represent a small percentage (approximately 1-5%) of the entire width amount, this results in unchanged device V_{T}.

Thus, where a lower threshold voltage is desired, a uniform boron concentration along the surface of well 110 may be targeted. To achieve such a distribution, dopants having an opposite charge of P-type well 110 are introduced into corners of the active region. For example, where well 110 is doped with boron (P-type), dopants 810 may be, but are not limited to arsenic, phosphorous or antimony. Dopants 810 may be introduced in any amount suitable for achieving the desired change in threshold voltage. For example, where an even lower threshold voltage is desirable, a higher concentration of arsenic may be implanted.

As shown in FIG. 8, dopants 810 are introduced into active regions 110 at an angle (e.g., 45 degrees to 60 degrees) relative to a top surface of structure 100. The introduction is adjacent trench 210. In an alternative embodiment, optional photoresist layers 830 may be formed on mask layers 120 overlying wells 105, 115 to protect adjacent devices (i.e. PMOSFET) defined by trench 210.

It should be recognized that changing of the device performance as described above may alternatively include increasing the threshold voltage. This can be useful for narrow devices used in circuits where low leakage (high V_{T}) operation is important. This may, for example, be achieved by doping corners of P-type well 110 with a boron species instead of arsenic. As a result of the further increase in boron concentration near gate electrode 1020 edges (see FIG. 10), the threshold voltage required to turn on the narrow width device is increased.

It should also be recognized that by use of dopants 810, an STI structure step height may be reduced (due to increased etch rate of implant damaged oxide) while an STI oxide divot remains unchanged. This additional effect results in improved topography and hence poly patterning uniformity and reduced gate leakage tails. Ultimately resulting in better product frequency (Fmax) vs. leakage (ISB) due to the abundance of narrow width devices used in product.

The different material density between, for example, the silicon nitride of mask layer 120 and the silicon dioxide in trenches 210, in one embodiment, is sufficient to allow penetration of dopants 810 to stop within active corner regions 820 of well 110 without penetration into the device channel region (under mask layer 120). Recess 710 in dielectric material 510 facilitates (and could be increased if necessary) the penetration of dopants 810 in the device width direction. After corners 820 are doped as shown in FIG. 8 they are activated to allow for changing of device performance (i.e. increase or decrease of V_{T}). Activation may be accomplished by heating structure 100 to a temperature on the order of 1000 degrees C. (° C.) for times on the order of 10 seconds (s).

In one embodiment, where changing the device performance includes decreasing the threshold voltage of a narrow width transistor having a well 110 doped with boron, arsenic may be introduced into an active region at a concentration of about 1E-18/cm3, this concentration is similar to a halo so that it effectively compensates the halo. The arsenic may be introduced at an angle of 10 to 40 degrees. In this aspect, it is to be recognized that the larger the angle of introduction, the wider the transistors that starts to respond to this process. The arsenic may be introduced at an implant energy of 40 to 60 kilo electron volts (keV), the upper energy depending on the thickness of the mask layer 120 over the silicon (in our case about 700 Å) which we don't want penetrate and the lower energy depending on the STI recess 710 we want to penetrate. The implant is introduced at a depth of 100-300 Å, similar to the depth of a halo implant, from the substrate surface.

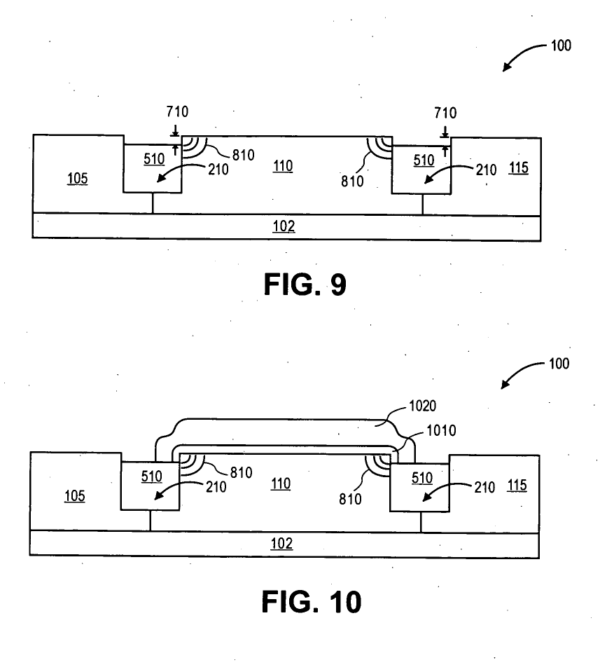

In one embodiment, once dopants 810 are introduced, mask layer 120 and photoresist layer 830 are etched as shown in FIG. 9 (block 1345, FIG. 13). In another embodiment where photoresist layer 830 is not present, mask layer 120 is etched once dopants 810 are introduced. FIG. 10 shows structure 100 of FIG. 9 after further processing to form gate dielectric 1010 over the surface of substrate 102 (block 1350, FIG. 13). Gate dielectric 1010 may be grown, such as for example where the gate dielectric is SiO₂, or deposited. It is to be appreciated that, in addition to SiO₂, other gate dielectrics may be used to further optimize the MOSFET transistor devices. Once gate dielectric 1010 is formed, gate electrode 1020 of a semiconductor (i.e., polycrystalline silicon or metal or both) is formed as further illustrated in FIG. 10. Formation may include a blanket deposit of polysilicon in the active area. The deposit may then be patterned using a photolithographic technique.

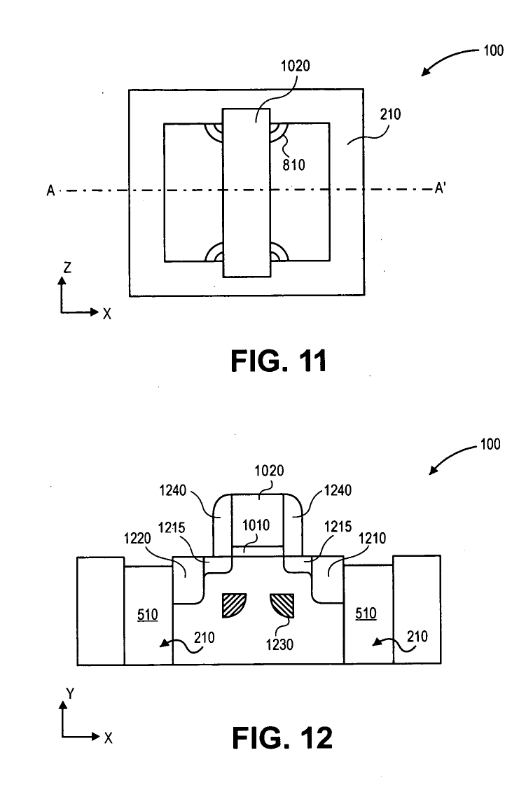

FIG. 11 is a schematic illustration of a top view of structure 100 of FIG. 10. As can be seen from the top view, anti-halo implants 810 are found at an active region adjacent an interface defined by trench 210 and gate electrode 1020. The term interface is used to refer to the point of intersection between trench 210 and gate electrode 1020. FIG. 12 shows a cross section of the structure of FIG. 11 through line A, A′ after the further processing operations of forming lightly doped junctions 1215, 1225, sidewall spacers 1240, source/drain junctions 1210, 1220 and halo implants 1230. With respect to a halo implant, a halo implant is typically a dopant species opposite the transistor type (N type for PMOS and P type for NMOS). The halo implant is rotated 90 degrees relative to an anti-halo. The halo dopant that normally diffuses is compensated by the presence of the anti-halo dopant in the device edge regions so that a net dopant profile will be uniform. In an alternative embodiment, a cross section of the structure of FIG. 11 may include lightly doped junctions 1215, 1225, sidewall spacers 1240 and source/drain junctions 1210, 1220.

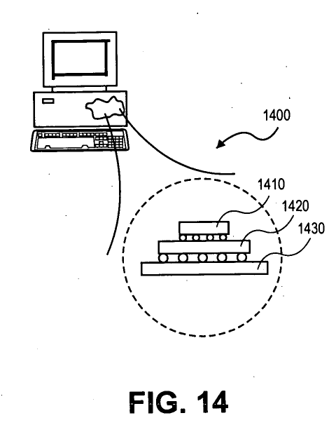

FIG. 14 shows a cross-sectional view of an integrated circuit package that can be physically and electrically connected to a printed wiring board or printed circuit board (PCB) to form an electronic assembly. The electronic assembly can be part of an electronic system such as a computer (e.g., desktop, laptop, handheld, server, etc.), wireless communication device (e.g., cellular phone, cordless phone, pager, etc.), computer-related peripheral (e.g., printer, scanner, monitor, etc.), entertainment device (e.g., television, radio, stereo, tape and compact disc player, video cassette recorder, MP3 (motion picture experts group, audio layer 3 player, etc.), and the like. FIG. 14 illustrates the package is part of a desktop computer. FIG. 14 shows electronic assembly 1400 including die 1410 physically and electrically connected to package substrate 1410. Die 1410 is integrated circuit die, such as a microprocessor die having transistor structures formed as described with reference to FIGS. 1-13. Electrical contact points (e.g., contact pad on a surface die 100) are connected to package substrate 1420 through, for example, a conductive bump layer. Package substrate 1420 may be used to connect die 1410 to printed circuit board 1430 such as a motherboard or other circuit board.

In the preceding detailed description, specific embodiments are illustrated, including a device having implants for changing device performance. It will, however, be evident that various modifications and changes may be made thereto without departing from the broader spirit and scope of the invention as set forth in the claims. For example, N-type devices have been described. It is contemplated that, the apparatus and method is suitable for P-type devices. Still further, changing of V_{T} is described, however, it is further contemplated that performance characteristics may further include, for example, I_{off} and I_{D}. The specification and drawings are, accordingly, to be regarded in an illustrative rather than a restrictive sense.

What is claimed is:

1. A method comprising:
forming a transistor structure comprising a gate electrode over an active region of a substrate, the active region defined by a trench isolation structure; and
changing a performance of a narrow width transistor with respect to a wide width transistor by introducing a dopant into the active region adjacent an interface defined by the trench isolation structure and the gate electrode.

2. The method of claim 1, wherein the performance relates to a threshold voltage and changing comprises one of increasing and decreasing the threshold voltage.

3. The method of claim 1, wherein introducing comprises implanting and activating the dopant.

4. A structure comprising:
a gate electrode formed on a substrate;
an active region adjacent an interface defined by a trench isolation structure and the gate electrode; and
an implant at the interface to change a performance of a transistor.

5. The structure of claim 4, wherein the performance relates to a threshold voltage and changing comprises one of increasing and decreasing the threshold voltage.

6. The structure of claim 4, wherein the species is arsenic.

7. The structure of claim 4, wherein the species is phosphorus.

8. The structure of claim 4, wherein the species is boron.

9. A method comprising:
forming a transistor device having an active region adjacent an interface defined by a trench isolation structure and a gate electrode;
forming a recess in the trench isolation structure; and
changing a performance of the transistor by introducing a dopant into the active region.

10. The method of claim 9, wherein the performance relates to a threshold voltage and changing comprises one of increasing and decreasing the threshold voltage.

11. The method of claim 9, wherein introducing comprises implanting the dopant and activating the dopant.

12. The method of claim 9, wherein the dopant comprises a species selected from the group consisting of arsenic, phosphorous and antimony.

13. The method of claim 9, wherein the dopant comprises one of boron and Indium.

14. The method of claim 11, wherein implanting is in a direction along a Z axis on laterally opposed sides of the gate.

15. A system comprising:
a computing device comprising a microprocessor, the microprocessor coupled to a printed circuit board, the microprocessor comprising a substrate having a plurality of circuit devices including transistors, wherein a transistor comprises:
a gate electrode formed on the substrate;
an active region adjacent an interface defined by a trench isolation structure and a gate electrode; and
an implant having a species within the active region to change a performance of the transistor.

16. The system of claim 15, wherein the performance relates to a threshold voltage and changing comprises one of increasing and decreasing the threshold voltage.

17. The system of claim 15, wherein the species is selected from the group consisting of arsenic, phosphorous and antimony.

18. The system of claim 15, wherein the species is one of boron and Indium.
